(19) United States
(12) Patent Application Publication
(10) Pub. No.: US 2011/0003450 A1
(43) Pub. Date: Jan. 6, 2011

(54) METHOD FOR MANUFACTURING SEMICONDUTOR DEVICE WITH STRAINED CHANNEL

(76) Inventors: Young-Ho LEE, Gyeonggi-do (KR); Tae-Hang Ahn, Gyeonggi-do (KR); Seung-Beom Baek, Gyeonggi-do (KR); Jun-Hee Cho, Gyeonggi-do (KR); Jeong-Seon Kim, Gyeonggi-do (KR)

Correspondence Address: IP & T GROUP LLP, 7700 Little River Turnpike, Suite 207, Annandale, VA, 22003, US

(21) Appl. No.: 12/646,207

(22) Filed: Dec. 23, 2009

(30) Foreign Application Priority Data
Jul. 3, 2009 (KR) 10-2009-0060876

(51) Int. Cl. H01L 21/336

(52) U.S. Cl. 438/285; 438/300; 257/E21.431

(57) ABSTRACT

A method for forming a semiconductor device includes forming a gate pattern over a silicon substrate, forming gate spacers over both sidewalls of the gate pattern, forming a dummy gate spacer over a sidewall of each one of the gate spacers, forming a recess region having inclined sidewalls extending in a direction to a channel region under the gate pattern by recess-etching the silicon substrate, filling the recess region with an epitaxial film, which becomes a source region or a drain region, through a selective epitaxial growth process, and removing the dummy gate spacer.

### CROSS-REFERENCE TO RELATED APPLICATIONS

The present application claims priority of Korean patent application number 10-2009-0060876, filed on Jul. 3, 2009, which is incorporated by reference in its entirety.

### BACKGROUND OF THE INVENTION

The present invention relates to a method for fabricating a semiconductor device, and more particularly, to a method for fabricating a semiconductor device having a strained channel.

Due to the high-integration of a semiconductor device, a gate insulating layer thickness and a channel length of a MOS device have been continuously reduced. Such reduction of the gate insulating layer thickness and the channel length increases the mobility of electrons or holes. That is, the reduction of the gate insulating layer thickness and the channel length improves the speed and operation current of a device.

However, the reduction of a channel length disadvantageously causes short channel effect. Further, the reduction of the gate insulating layer thickness increases gate leakage current. In order to overcome the problem of the short channel effect, a large amount of impurities is doped in a channel. That is, the doped impurities disturb carrier movement. Accordingly, the doped impurities degrade the mobility of carriers although a channel length is reduced.

In order to improve an operation speed and operation current of a device, many methods for increasing carrier mobility have been introduced. Particularly, a method for forming a strained channel has been receiving attention. The method for forming a strained channel according to the related art recesses a source/drain region around a gate side wall through etching and applies stress to a channel by selectively depositing an epitaxial thin film of group 4 elements having a lattice constant different from that of a silicon substrate.

Hereinafter, a method for forming a strained channel by selectively filling the recessed source/drain region with epitaxial silicon-germanium (SiGe) or silicon-carbon (SiC) according to the related art will be described with reference to the accompanying drawings.

FIGS. 1A to 1D are diagrams illustrating a method for manufacturing a semiconductor device having a strained channel according to the related art.

As show in FIG. 1A, a field oxide layer 12 is formed over a silicon substrate 11 to isolate one device from another. Then, a gate pattern is formed over the field oxide layer 12. Here, the gate pattern includes a gate insulating layer 13, a gate polysilicon layer 14, a gate conductive layer 15, and a gate hard mask layer 16.

After forming the gate pattern, gate spacers 17 are formed on both sidewalls of the gate pattern, and a recess region 18 is formed by recessing a predetermined region of source/drain regions to a predetermined depth.

As shown in FIG. 1B, an epitaxial film 19 is formed over the recess region 18 through a selective epitaxial growth (SEG) process. The epitaxial film 19 includes silicon-germanium (SiGe), silicon-carbon (SiC), or silicon-germanium-carbon (SiGeC) each having a lattice constant different from that of the silicon substrate 11.

A size of a channel strain formed by the epitaxial film 19 increases in proportion to the increase of germanium concentration or carbon concentration, the increase of a lateral width of the gate spacer, and the increase of a recess depth.

However, when a channel length becomes short due to the high integration of a device, or when a deep recess is formed and In-Situ doping is performed, a junction depth becomes significantly large. Accordingly, device characteristics may be degraded due to a short channel effect. In other words, although a recess depth should be deep for obtaining a strained channel effect, the short channel effect becomes worse in proportion to the recess depth. Accordingly, there is a limitation on the recess depth that may be utilized.

In order to overcome such a short channel effect problem, an impurity doped epitaxial film 21A is formed by performing ion implantation (see arrow of FIG. 1C) after depositing an un-doped epitaxial film 20 as shown in FIGS. 1C and 1D. In another method (not shown in the accompanying drawings), an un-doped epitaxial film is partially deposited and a stack is formed at a remaining part through In-Situ doping. However, each of these methods have the following shortcomings.

In the method of performing ion implantation after depositing un-doped epitaxial film 20, it is difficult to control an ion-implantation depth and profile due to a facet formed around a field oxide layer 12. That is, an inability to control the implantation depth forms a doping profile, as shown in FIG. 1D, because of the facet formed around the field oxide layer 12 of the un-doped epitaxial film 20 (shown in FIG. 1C). Accordingly, the device characteristics are degraded due to the short channel effect and an increase of the junction leakage current.

The method of partially depositing un-doped epitaxial film and depositing In-Situ doped epitaxial film as deep as a junction depth slightly overcomes the short channel effect problem and junction leakage current problem. However, this method does not entirely overcome the difficulty of controlling the doping profile because the facet is still created. In the case of a DRAM for storing data, the number of transistors at a peripheral circuit is abruptly increased according to an increase of the integration degree. Accordingly, a distance between a gate pattern and an adjacent field oxide 12 layer becomes close. Thus, the existence of a facet significantly contributes to the short channel effect problem. Therefore, this method also does not overcome the above problems.

### SUMMARY OF THE INVENTION

Embodiments of the present invention are directed to providing a method for manufacturing a semiconductor device capable of suppressing short channel effect while maximizing strained channel effect.

Embodiments of the present invention are directed to providing a method for manufacturing a semiconductor device capable of preventing a facet from being generated around a field oxide layer when an epitaxial film is formed in a recess region for a strained channel.

In accordance with an aspect of the present invention, there is provided a method for forming a semiconductor device, including forming a gate pattern over a silicon substrate, forming gate spacers over both sidewalls of the gate pattern, forming a dummy gate spacer over a sidewall of each one of the gate spacers, forming a recess region having inclined sidewalls extending in a direction to a channel region under the gate pattern by recess-etching the silicon substrate, filling the recess region with an epitaxial film that becomes a source region or a drain region through a selective epitaxial growth process, and removing the dummy gate spacer.

In accordance with a further aspect of the present invention, there is provided a method for fabricating a semiconductor device including forming a gate pattern over a silicon substrate having a field oxide layer, forming gate spacers over both sidewalls of the gate pattern, forming a dummy gate spacer over a sidewall of each one of the gate spacers, forming a recess region having inclined sidewalls having a predetermined slope by recess-etching the silicon substrate between the dummy gate spacer and the field oxide layer, filling the recess region with an epitaxial film through a selective epitaxial growth process, wherein the epitaxial film becomes a source region and a drain region, and removing the dummy gate spacer.

### BRIEF DESCRIPTION OF THE DRAWINGS

FIGS. 1A to 1D are diagrams illustrating a method for fabricating a semiconductor device having a strained channel according to the related art.

FIGS. 2A to 2E are diagrams illustrating a method for fabricating a semiconductor device having a strained channel in accordance with an embodiment of the present invention.

FIG. 3 is a picture showing an epitaxial film grown in accordance with an embodiment of the present invention.

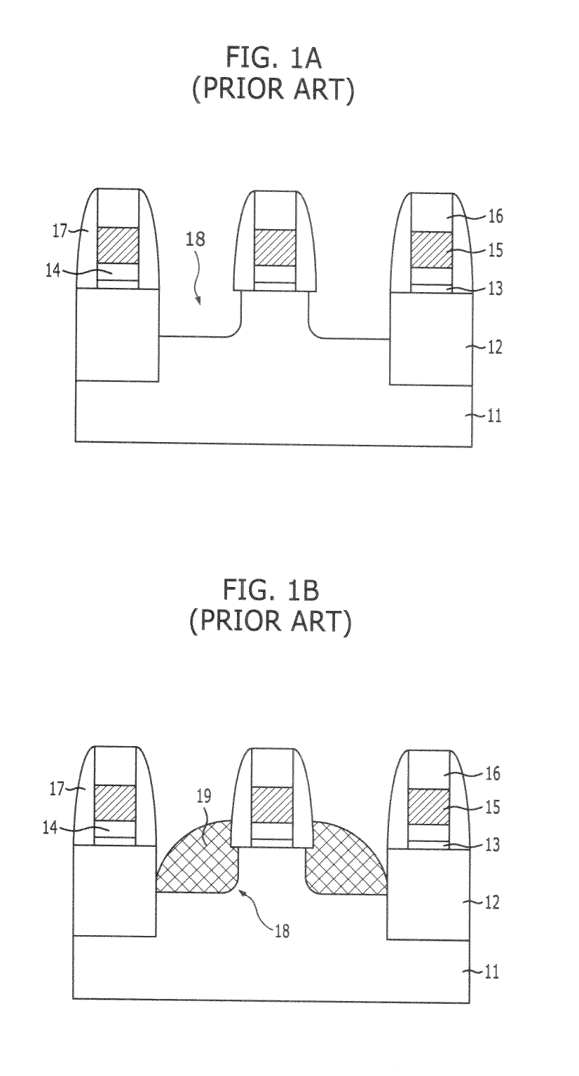

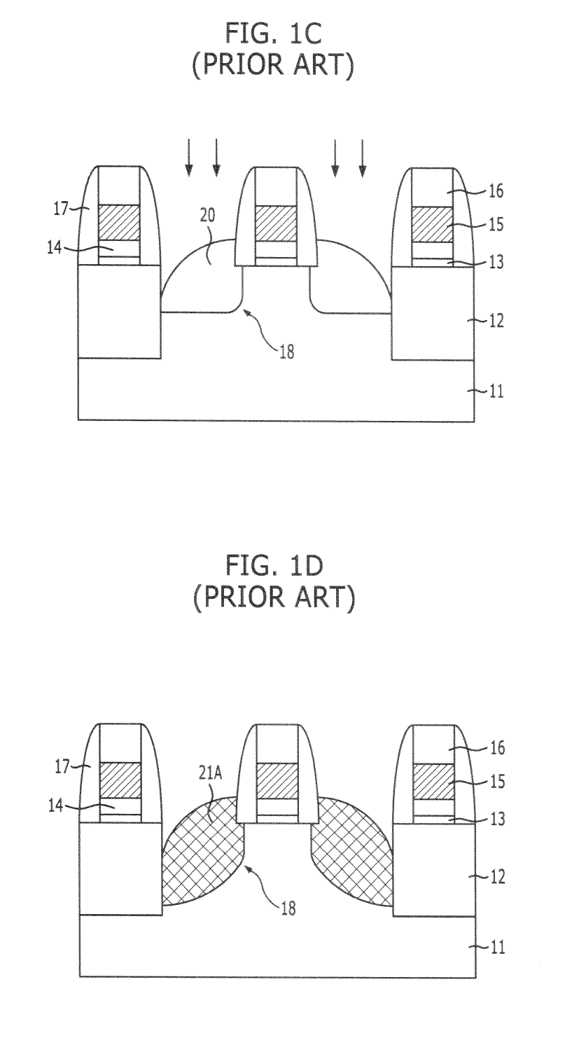

### DESCRIPTION OF SPECIFIC EMBODIMENTS

Other objects and advantages of the present invention can be understood by the following description, and become apparent with reference to the embodiments of the present invention.

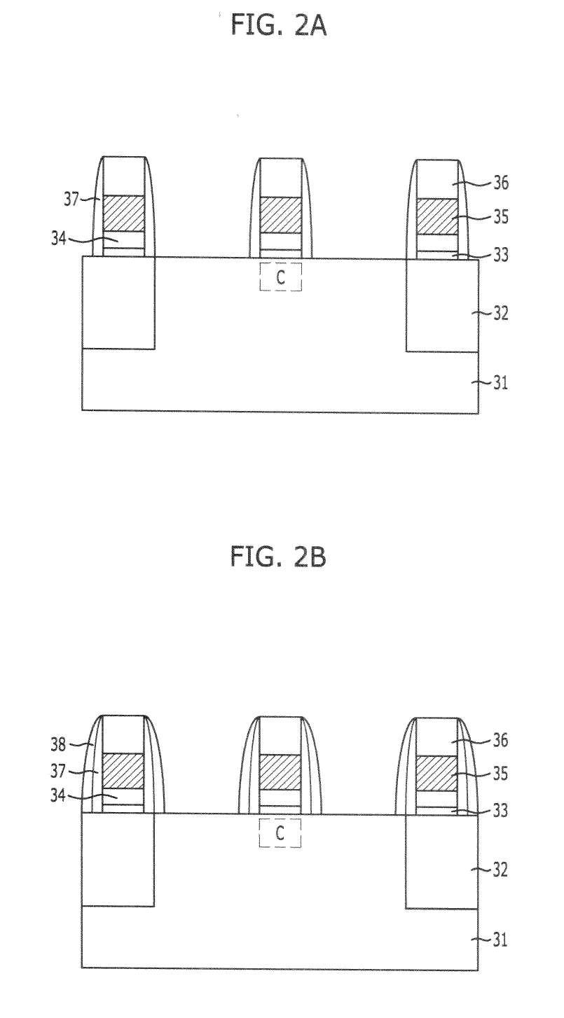

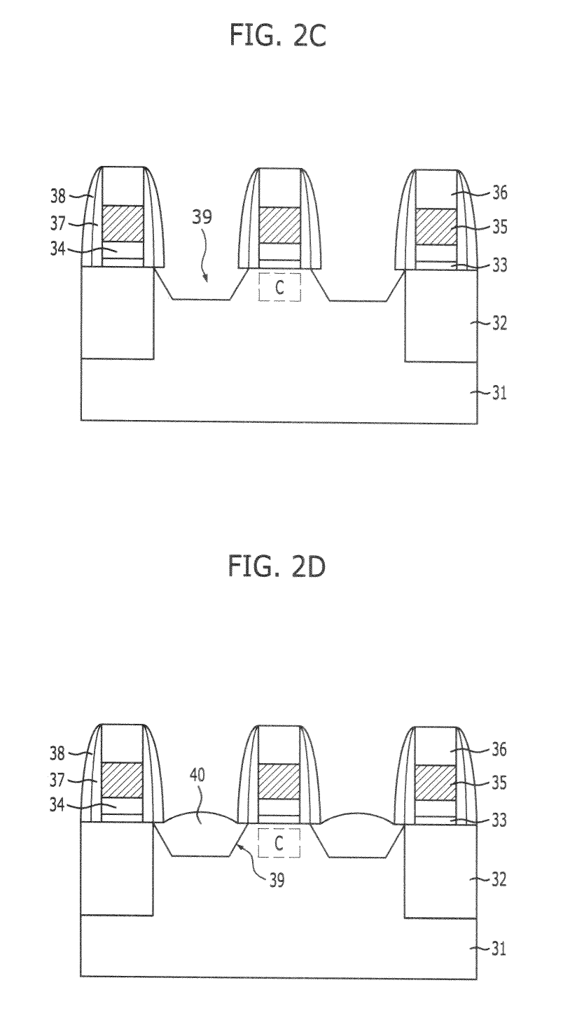

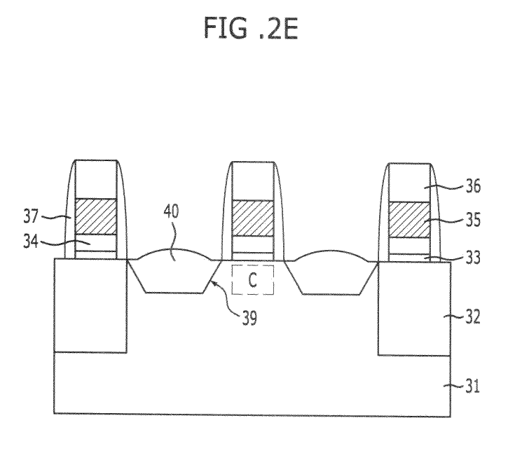

FIGS. 2A to 2E are diagrams illustrating a method for fabricating a semiconductor device having a strained channel in accordance with an embodiment of the present invention.

As shown in FIG. 2A, a field oxide layer 32 is formed in a silicon substrate 31 to isolate one device from another. The field oxide layer 32 may be formed using an STI process. The field oxide layer 32 defines an active area.

A gate pattern including a gate insulating layer 33, a gate polysilicon layer 34, a gate conductive layer 35, and a gate hard mask layer 36 is formed. A channel region C is formed below the gate pattern.

Gate spacers 37 are formed on both sidewalls of the gate pattern. The gate spacers 37 may be formed by depositing a spacer insulating layer and etching back the spacer insulating layer.

The spacer insulating layer used for forming the gate spacers 37 may be a single layer, such as a nitride layer or an oxide layer. Further, the spacer insulating layer may be a stacked layer including a nitride layer and an oxide layer.

As shown in FIG. 2B, a dummy gate spacer 38 is formed on a sidewall of each gate spacer 37. The dummy gate spacers 38 may be formed of material that can be removed by a following process. For example, the dummy gate spacer 38 may be formed of an oxide layer or a stacked layer including an oxide layer and a nitride layer. Although, preferably, the dummy gate spacer 38 is formed of an oxide layer. The dummy gate spacer 38 may be formed by depositing an oxide layer and etching back the oxide layer.

If the dummy gate spacers 38 are formed as shown in FIG. 2B, a width of the channel region C becomes smaller in proportion to a distance between dummy gate spacers 38 on the same gate pattern than in proportion to a distance between gate spacers 37 on the same gate pattern.

As shown in FIG. 2C, the silicon substrate 31 is placed in a thin film deposition apparatus for a selective epitaxial growth (SEG) process.

Then, the silicon substrate 31 under the dummy gate spacer 38 is recessed at a predetermined depth by performing an isotropic etching using an etching gas in the thin film deposition apparatus. Before the silicon substrate 31 is placed in the thin film deposition apparatus, one of an In-Situ dry cleaning process and an In-Situ wet cleaning process may be performed. Or, both the In-Situ dry cleaning process and the In-Situ wet cleaning process may be performed. Such In-Situ cleaning processes expose a clean surface of a silicon substrate by removing a natural oxide layer and other surface pollutants. In order to minimize the loss of the gate spacer 37 and the dummy gate spacer 38, gas or solution having a proper selectivity is used during the In-Situ cleaning process. The In-Situ cleaning process is performed at a temperature ranging from a normal temperature to about 600° C.

As described above, a recess region 39 is formed to have a predetermined depth by performing isotropic etching. The recess region 39 includes inclined sidewalls having a predetermined slope and a flat bottom surface. More specifically, the recess region 39 has an etching slope profile such that the inclined sidewall closest to the channel region C has a greater depth at points farther from the channel region C.

An isotropic etching gas, such as hydrogen chloride HCl and chlorine Cl₂ may be used to isotropically etch the silicon substrate 31 thereby forming the recess 39.

The recess etching may be performed using a separate chamber under the condition that a following deposition process and a vacuum state are not disturbed. Further, the recess etching may be performed using an additional isotropic wet solution under the condition that a following deposition process and a vacuum state are not disturbed.

The depth of the recess etching may be decided according to the amount of stress that may be applied to a channel necessary to obtain the desired device characteristics. Preferably, the depth of the recess etching is about 100 Å to 1000 Å.

A lateral etching distance of recess etching is controlled to be maximally recessed in consideration of a thickness of the gate spacer 37, a channel length, and a height of the gate pattern.

The recess etching may be controlled to form a recess region under the gate spacer 37 or the dummy gate spacer 38. Further, the recess etching may be controlled, so that a side of the field oxide layer 32 is not exposed (i.e., the silicon substrate 31 continues to cover the side of the field oxide layer 32).

After the recess etching, an epitaxial film 40 is formed in the recess region 39 by continuously performing a selective epitaxial growth process. The epitaxial film 40 later becomes a source region and a drain region. The epitaxial film 40 may be a single layer made of silicon-germanium (SiGe), a silicon carbon (SiC), or silicon-germanium-carbon (SiGeC). Alternatively, the epitaxial film 40 may be a stacked layer formed of a silicon layer and a silicon-germanium layer, or a silicon-carbon layer and a silicon layer. In the case of a PMOS device, a Boron doped epitaxial silicon-germanium layer (or a stacked layer of a silicon layer and a silicon-germanium layer) is used. The Boron causes a compressive stress because the Boron includes a lattice constant higher than that of the silicon substrate thereby improving the mobility of the holes which act as carriers. In the case of an NMOS device, phosphorus (P) or arsenic (AS) doped epitaxial silicon-carbon layer (or a stacked layer of a silicon layer and a silicon-carbon layer) is used. Both the phosphorus (P) and the arsenic (AS) cause tensile stress because the phosphorus and the arsenic both have a lattice constant smaller than that of the silicon substrate thereby improving the mobility of the electrons which act as carriers.

The epitaxial film 40 may be formed using a Low Pressure CVD (LPCVD) apparatus, a Very Low Pressure CVD (VLPCVD) apparatus, a Plasma Enhanced-CVD (PE-CVD) apparatus, an Ultrahigh Vacuum CVD (UHVCVD) apparatus, a Rapid Thermal CVD (RTCVD) apparatus, an Atmosphere Pressure CVD (APCVD) apparatus, or a Molecular Beam Epitaxy (MBE) apparatus.

The deposition temperature of the epitaxial film 40 is in a range of about 400 to 800° C.

A facet is not formed in the epitaxial film 40 if the epitaxial film 40 is grown by the selective epitaxial growth process as described above. Therefore, it is possible to control a dopant profile by using an In-Situ doping method or by performing a following ion implantation process without doping.

The epitaxial film 40 is formed to be higher than a lower part of the dummy gate spacer 38. After forming the epitaxial film 40, the dummy gate spacer 38 is removed. Accordingly, a surface area of the epitaxial film 40 is increased, so it is possible to reduce surface resistance.

A size of a channel strain created by the epitaxial film 40 increases in proportion to the increase of germanium concentration or carbon concentration, the increase of a bottom lateral depth of a gate space, and the increase of the recess depth. The germanium concentration or carbon concentration is decided according to the device property. Preferably, the germanium concentration is about 5% to 50%, and the carbon concentration is about 0.1% to 10%.

The epitaxial film 40 is deposited at a predetermined thickness higher than a lower part of the dummy gate spacer 38. Accordingly, the upper surface of the epitaxial film 40 becomes higher than the bottom surface of the gate spacer 37 after the dummy gate spacer 38 is removed. The thickness of the epitaxial film 40 is decided according to a recess depth and the desired device characteristics. Preferably, the thickness of the epitaxial film 40 is in a range of about 100 Å to about 2,000 Å.

The epitaxial film 40 is doped through In-Situ doping. Alternatively, the epitaxial film 40 may be doped through ion implantation in a subsequent process. Such an ion implantation process may be performed before or after removing the dummy gate spacer 38.

As shown in FIGS. 2C and 2D, an interface defect is suppressed between the silicon substrate 31 and the epitaxial film 40 by continuously performing the recess etching and epitaxial film deposition. Further, the defect of the epitaxial film 40 is suppressed.

As shown in FIG. 2E, a semiconductor device having a strained channel is completely manufactured by performing the following device manufacturing processes after removing the dummy gate spacer 38.

The dummy gate spacer 38 may be removed right after depositing the epitaxial film 40. Or, the dummy gate spacer 38 may be used to prevent additional ion implantation thereby reducing resistance and improving the short channel effect of the channel region C.

Further, silicide may be formed by the following process. The surface resistance of the source region and the drain region can be reduced using titanium silicide (TiSi₂), cobalt silicide (CoSi2), and nickel silicide (NiSi).

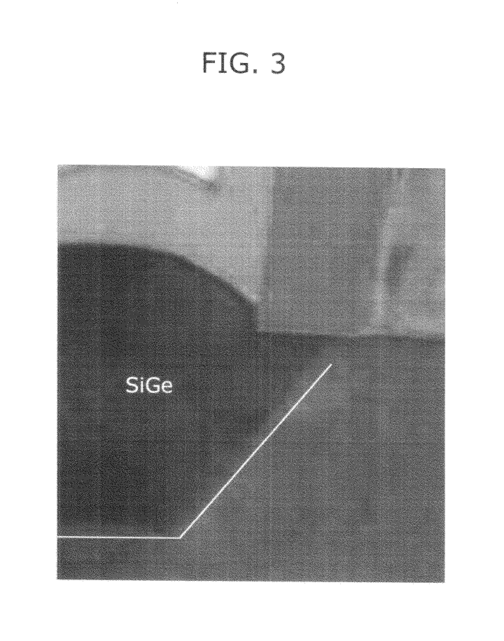

FIG. 3 is a picture showing an epitaxial film grown in accordance with an embodiment of the present invention. As shown in FIG. 3, an epitaxial film made of SiGe is formed without a facet being created around a field oxide layer. Further, the picture clearly shows a recess region leaving a predetermined amount of silicon substrate around the field oxide layer and having a predetermined slope.

As described above, the In-Situ recess etching is performed using an etching gate in a thin film deposition apparatus after forming the dummy gate spacer 38 made of a material that can be removed by a subsequent process. Accordingly, the short channel effect is suppressed by maximizing the strain channel effect while controlling a slope profile of the recess such that the recess becomes deeper at points further from the channel region. Further, the In-Situ recess etching prevents a facet from being generated around the field oxide layer and reduces the surface resistance due to an increase of the surface area of the epitaxial film 40, which is exposed after removing the dummy gate spacer 38. Therefore, a high quality epitaxial film 40 can be obtained by the In-Situ recess etching method according to the present embodiment.

In the embodiments of the present invention, the removable dummy gate spacer 38 is additionally formed after forming the gate spacers 37. Then, the In-Situ isotropic recess etching is performed in a thin film deposition apparatus using an etching gas of hydrogen chloride HCl and chlorine Cl₂. Accordingly, it is possible to suppress the short channel effect while maximizing channel strain effect by controlling an etching profile to form recesses 39 having inclined sides that slope towards each other as their depths increase.

Further, a facet is prevented from being formed by leaving a part of a silicon substrate 31 at a side of the field oxide layer 32 due to the recess etching. Moreover, the surface resistance can be reduced because the selective epitaxial thin film 40 surface exposed after removing the dummy gate spacer 38 increases compared with that of the related art.

Unlike the related art, the recess region is formed by the In-Situ recess etching in the thin film deposition apparatus before depositing the epitaxial film 40. Thus, it is possible to sustain a clean interface between the substrate 31 and the thin film 40. Therefore, a high quality selective epitaxial thin film 40 can be obtained as well as an improved junction leakage current.

Further, it is possible to shorten a fabrication time by performing a recess etching process and a deposition process as one process.

The present invention relates to a method for fabricating a semiconductor device, and more particularly, to a method for fabricating a semiconductor device having a strained channel. As described above, the method for manufacturing a semiconductor device having a strained channel according to the present invention can suppress short channel effect while maximizing strain effect by controlling an etching profile of a recess region using the dummy gate spacer 38.

Further, a facet is prevented from being formed around the field oxide layer 32 by controlling the etching profile of the recess region 39, and the surface resistance is reduced due to the increased surface area of the epitaxial film 40, which is exposed after removing the dummy gate spacer 38.

Moreover, unlike the related art, the In-Situ recess etching is performed in the thin film deposition apparatus before deposition, so the interface between the silicon substrate 31 and the epitaxial film 40 remains clean. Accordingly, a high quality epitaxial film 40 can be obtained, and it is possible to obtain a device with an improved junction leakage current property.

While the present invention has been described with respect to the specific embodiments, it will be apparent to those skilled in the art that various changes and modifications may be made without departing from the spirit and scope of the invention as defined in the following claims.

What is claimed is:

1. A method for forming a semiconductor device, comprising:
forming a gate pattern over a silicon substrate;
forming gate spacers over both sidewalls of the gate pattern;
forming a dummy gate spacer over a sidewall of each one of the gate spacers;
forming a recess region having inclined sidewalls extending in a direction to a channel region under the gate pattern by recess-etching the silicon substrate;
filling the recess region with an epitaxial film for a source region or a drain region through a selective epitaxial growth process; and
removing the dummy gate spacer.

2. The method of claim 1, wherein each inclined sidewall of the recess region closest to the channel region under the gate pattern has a greater depth at points farther from the channel region.

3. The method of claim 1, wherein the dummy gate spacer comprises an oxide layer.

4. The method of claim 1, wherein the forming of the recess region is performed by an isotropic etching.

5. The method of claim 1, wherein the forming of the recess region comprises performing In-Situ recess etching on the silicon substrate in a deposition apparatus used for the selective epitaxial growth process.

6. The method of claim 5, wherein a cleaning process is performed before the silicon substrate is placed in the deposition apparatus used for the selective epitaxial growth process.

7. The method of claim 1, wherein the epitaxial film is grown to have a thickness higher than an interface between the dummy gate spacer and the silicon substrate during the selective epitaxial growth process.

8. The method of claim 1, wherein the epitaxial film is one selected from a group consisting of a silicon-germanium layer, a silicon carbon layer, and a silicon-germanium-carbon layer.

9. A method for fabricating a semiconductor device, comprising:
forming a gate pattern over a silicon substrate having a field oxide layer;
forming gate spacers over both sidewalls of the gate pattern;
forming a dummy gate spacer over a sidewall of each one of the gate spacers;
forming a recess region having inclined sidewalls having a predetermined slope by recess-etching the silicon substrate between the dummy gate spacer and the field oxide layer;
filling the recess region with an epitaxial film through a selective epitaxial growth process, wherein the epitaxial film becomes a source region and a drain region; and
removing the dummy gate spacer.

10. The method of claim 9, wherein the inclined sidewall closest to a channel region under the gate pattern has a greater depth at points farther from the channel region.

11. The method of claim 9, wherein the dummy gate spacer comprises an oxide layer.

12. The method of claim 9, wherein the forming of the recess region is performed by an isotropic etching.

13. The method of claim 9, wherein the forming of the recess region comprises performing In-Situ recess etching on the silicon substrate in a deposition apparatus used for the selective epitaxial growth process.

14. The method of claim 13, wherein a cleaning process is performed before placing the silicon substrate in the deposition apparatus used for the selective epitaxial growth process.

15. The method of claim 9, wherein the epitaxial film is grown to have a predetermined thickness higher than an interface between the dummy gate spacer and the silicon substrate during the selective epitaxial growth process.

16. The method of claim 9, wherein the epitaxial film is one selected from a group consisting of a silicon-germanium layer, a silicon carbon layer, and a silicon-germanium-carbon layer.
